(19) United States
(12) Patent Application Publication
(10) Pub. No.: US 2005/0263854 A1
(43) Pub. Date: Dec. 1, 2005

(54) Thick laser-scribed GaN-on-sapphire optoelectronic devices

(76) Inventors: Bryan S. Shelton, Bound Brook, NJ (US); Hari S. Venugopalan, Somerset, NJ (US); Sebastien Libon, Tervuren (BE); Ivan Eliashevich, Maplewood, NJ (US)

Correspondence Address: Scott A. McCollister, Esq.;Fay, Sharpe, Fagan, Minnich & McKee, LLP, Seventh Floor, 1100 Superior Avenue, Cleveland, OH, 44114-2518, US

(21) Appl. No.: 11/123,796

(22) Filed: May 6, 2005

Related U.S. Application Data
(63) Continuation-in-part of application No. 10/146,267, filed on May 15, 2002.
Application No. 10/146,267 is a continuation-in-part of application No. 09/178,287, filed on Oct. 23, 1998, now Pat. No. 6,413,839.
(60) Provisional application No. 60/568,725, filed on May 6, 2004.

(51) Int. Cl. H01L 29/20; H01L 21/461

(52) U.S. Cl. 257/615; 438/460; 438/463; 257/620

(57) ABSTRACT

A sapphire wafer having a thickness greater than 125 microns and having devices disposed thereon is laser scribed to form a grid array pattern of laser scribe lines laser scribed into the sapphire wafer. The sapphire wafer is separated along the laser scribe lines to separate a plurality of device dice defined by the grid array pattern of laser scribe lines. Each device die includes (i) a device and (ii) a portion of the sapphire wafer having the thickness greater than 125 microns. In some embodiments, a GaN LED device die includes a GaN based LED device, and a sapphire substrate supporting the GaN based LED device. The sapphire substrate has: (i) a thickness greater than 125 microns effective for increased light extraction due to a lower critical angle for total internal reflection; and (ii) sides generated by laser scribing.

This application claims the benefit of U.S. Provisional Application No. 60/568,725 filed May 6, 2004, entitled “Thick Laser-Scribed GaN-on-sapphire Optoelectronic Devices” which is incorporated herein by reference in its entirety.

The following U.S. patents and U.S. published applications: U.S. Patent Appl. Publ. No. 2002/0127824 A1, publication date Sep. 12, 2002; U.S. Patent Appl. Publ. No. 2002/0177288 A1, publication date Nov. 28, 2002; U.S. Patent Appl. Publ. No. 2003/0003690 A1, publication date Jan. 2, 2003; and U.S. Pat. No. 6,413,839 issued Jul. 2, 2002; are each incorporated by reference herein in its entirety.

### BACKGROUND

The following relates to the light emitting diode (LED) arts. It finds particular application in conjunction with the separation of a plurality of GaN-based light emitting diode (LED) devices formed on or disposed on a sapphire wafer, and with LED device die formed by same, and will be described with particular reference thereto. However, the following is more generally applicable device die formed by separation of electronic or optoelectronic devices formed on or disposed on a wafer of substantially any material, and is also amenable to other like applications and device dice.

In order to fully separate or dice individual optoelectronic devices formed on a thick sapphire substrate, scribe lines are created along streets between the devices. These scribe lines can be cut into one or both sides of the wafer. After the scribe lines are created, applying a force on either side of the scribe line fractures the wafer. If the combination of one or both of the scribe lines go completely through the device, fracturing can be omitted.

Because sapphire is a very hard material; the thickness of the sapphire affects the fracture yield. Normally, for diamond scribe-and-break technology, this thickness is very thin, e.g., between 50 and 150 microns. As the thickness increases further, a dicing saw can be used to separate or dice the individual optoelectronic device dies from the thick sapphire substrate. However, dicing saws introduce a large kerf width to the wafer, corresponding to wide streets and fewer device die yielded per wafer.

### BRIEF SUMMARY

In some embodiments, a method for dicing a device wafer disposed on sapphire is disclosed. A sapphire wafer having a thickness greater than 125 microns and having devices disposed thereon is laser scribed to form a grid array pattern of laser scribe lines laser scribed into the sapphire wafer. The sapphire wafer is separated along the laser scribe lines to separate a plurality of device dice defined by the grid array pattern of laser scribe lines. Each device die includes (i) a device and (ii) a portion of the sapphire wafer having the thickness greater than 125 microns.

In some embodiments, a device die is disclosed, including an electronic or optoelectronic device, and a sapphire substrate supporting the electronic or optoelectronic device. The sapphire substrate has a thickness greater than 125 microns and sides generated by laser scribing.

In some embodiments, a GaN LED device die is disclosed, including a GaN based LED device, and a sapphire substrate supporting the GaN based LED device. The sapphire substrate has: (i) a thickness greater than 125 microns effective for increased light extraction due to a lower critical angle for total internal reflection; and (ii) sides generated by laser scribing.

### DRAWINGS

FIGS. 1A and 1B diagrammatically show side and top (plan) views, respectively, of a sapphire wafer with devices disposed thereon, with a grid array pattern of scribe lines laser scribed into the sapphire wafer.

FIG. 2 diagrammatically shows a perspective view of one device die defined by the grid array pattern of scribe lines after separating the sapphire wafer along the scribe lines to separate a plurality of device dice.

### DETAILED DESCRIPTION

The following relates to optoelectronic devices, such as devices made from GaN-based semiconductor material, disposed on a thick sapphire substrate, formed via laser scribes on one or both sides of the chip. The typical device thickness is between 125 to 600 micron.

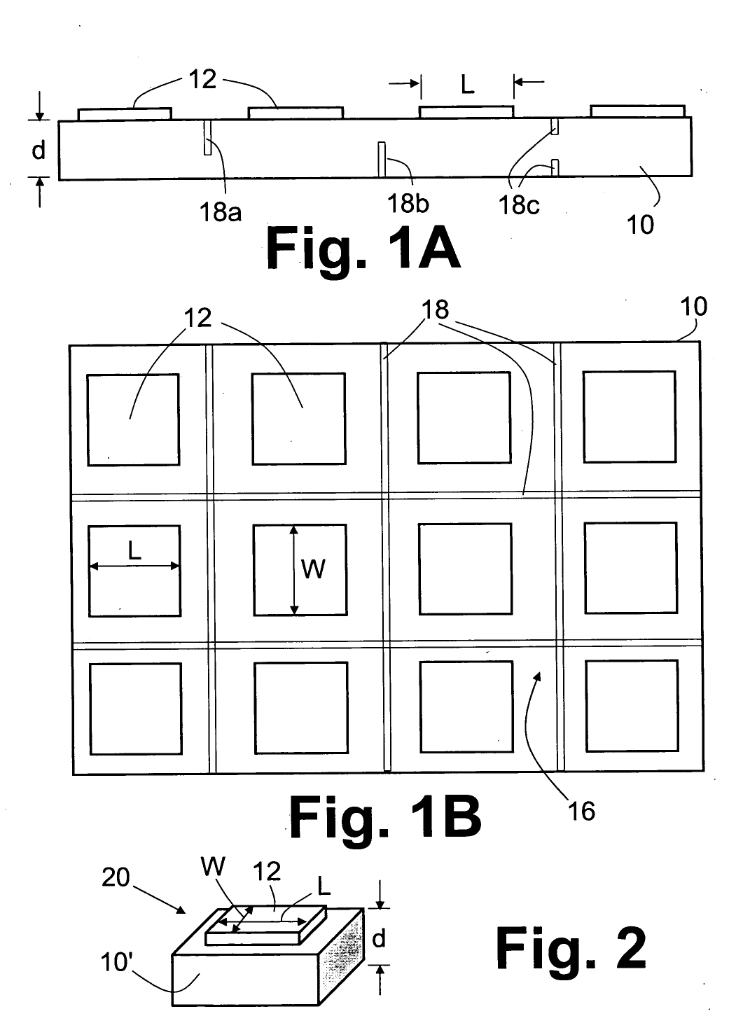

With reference to FIGS. 1A and 1B, a sapphire substrate 10 has a plurality of electronic or optoelectronic devices 12 disposed thereon. The sapphire substrate has a thickness d of greater than 125 microns. In some embodiments the substrate thickness d is less than 600 microns. Lateral dimensions L, W of each device 12 are in some embodiments 350 micron per side or greater. The dimensions L and W need not be the same, and moreover each device 12 can have a lateral shape other than the illustrated rectangular shape; for example, the devices can have a circular, elliptical, triangular, or otherwise-shaped area.

In some embodiments, the devices 12 are GaN-based light emitting diode (LED) devices formed by epitaxially depositing a sequence of group III-nitride layers (such as layers of GaN, AlN, InN, or binary, ternary, or higher-order alloy combinations thereof) defining a pn junction on the sapphire substrate 10 using metal-organic chemical vapor deposition (MOCVD), molecular beam epitaxy (MBE), or another epitaxial crystal growth technique. The sequence of group III-nitride layers is processed using a suitable sequence of device fabrication operations, such as etching to define mesas and to expose portions of the underlying layers, passivation by deposition of suitable insulative films, metallization operations, and so forth, to define the LED devices 12. While GaN-based LED devices 12 are illustrated, it is to be appreciated that other electronic or optoelectronic devices can be formed, such as lasers, transistors, or so forth. Moreover, the substrate 10 in some embodiments is made of a material other than sapphire, such as GaAs, GaP, SiC, GaN, or so forth.

Laser scribing is advantageous for fabricating a thick die from a thick wafer substrate because it has the advantages of diamond-tip scribing (namely, small kerf width and a smooth edge) as well as the advantages of sawing (namely, high separation yield and die that are consistently similar in size). Accordingly, laser scribing is employed to form a grid array pattern 16 of laser scribe lines 18 laser scribed into the sapphire wafer 10.

With particular reference to FIG. 1A, in some embodiments the laser scribing is performed on the front-side of the sapphire wafer 10 (that is, the side on which the devices 12 are disposed) to produce laser scribe lines 18a on the frontside of the sapphire wafer 10. In other embodiments, the laser scribing is performed on the back-side of the sapphire wafer 10 (that is, the side opposite the side on which the devices 12 are disposed) to produce laser scribe lines 18b on the frontside of the sapphire wafer 10. In still other embodiments, the laser scribing is performed on both the front-side and the back-side of the sapphire wafer 10 to produce laser scribe lines 18c having laser scribe line components on both the frontside and backside of the sapphire wafer 10.

With reference to FIG. 2, an optoelectronic device die 20 with a thick sapphire substrate 10′ having the thickness d greater than 125 micron thick, and in some embodiments greater than 125 microns and thinner than 600 microns, is formed by the aforementioned laser scribing on one or both sides of the sapphire substrate 10 to form the grid array pattern 16 of laser scribe lines 18, and subsequent separation along the laser scribe lines into the individual dice 20, which are ready to be packaged. While FIGS. 1A and 1B show a very small illustrative 3×4 array of devices 12, preferably the wafer 10 supports hundreds or thousands of devices 12 prior to separation. In some embodiments, the depth of the laser scribe lines 18 is between 25 and 66 percent of the total wafer thickness to promote easy fracturing and high fracture yield. In the case of the laser scribe lines 18c having both front-side and back-side laser scribe line components, in some embodiments the two laser scribe line components combine to be between 25 and 66 percent of the total wafer thickness to promote easy fracturing and high fracture yield. In some other embodiments, the laser scribe lines 18 pass entirely through the thickness d of the sapphire wafer 10, so that the scribing effectuates the die separation without subsequent fracturing. U.S. Patent Application Publication No. 2002/0127824 A1, which is incorporated herein by reference in its entirety, discloses some example laser scribing techniques.

Before the advent of laser scribing technology, the field of separating sapphire wafers was very stable. The dominating designs are dicing saw and scribe-and-break, for thick and thin wafers, respectively. Newer techniques, however, such as laser scribing and etching trenches have been developed to certain extents. In particular, the techniques disclosed herein relate to and/or complement the approach and/or techniques described in the U.S. Patent Application Publication No. 2002/0127824 A1.

The optoelectronic chip 20 having a thick sapphire substrate 10′ with thickness greater than 125 microns has advantages including increased light extraction because of lower critical angle for total internal reflection, elimination of the costly thinning process steps (in time, expense, and yield), ease of handling, and robustness of the chip. In addition, the shape of the chip can be shaped as desired and is very consistent over the entire wafer. This aids in subsequent mounting stages because of higher yield and easier inspection for automatic inspection stations.

The foregoing illustrated example relates to a GaN-on-sapphire chip laser-cut on one or both sides to provide high yield device singulation on thick sapphire substrates. Development work has been conducted on thick optoelectronic chips such as the example device die or chip 12 described herein to evaluate epitaxial LED wafers and enhancements in the processing of LEDs and the packaging of the LEDs. The initial studies were done for devices that were small (dimensions L, W about 350 micron length and width); however, devices of this size on thick sapphire tended to show high buildup of stress in the substrate. The ratio of these devices was 0.875:1 for a sapphire wafer thickness d of 400 micron. It has been determined that sapphire substrates above 125 micron thick benefit from at least a 2:1 ratio of device length and width L, W to the sapphire thickness d.

The preferred embodiments have been described. Obviously, modifications and alterations will occur to others upon reading and understanding the preceding detailed description. It is intended that the following claims be construed as including all such modifications and alterations.

The appended claims follow.

1. A method for dicing a device wafer disposed on sapphire, the method comprising:
laser scribing a sapphire wafer having a thickness greater than 125 microns and having devices disposed thereon to form a grid array pattern of laser scribe lines laser scribed into the sapphire wafer; and
separating the sapphire wafer along the laser scribe lines to separate a plurality of device dice defined by the grid array pattern of laser scribe lines, each device die including (i) a device and (ii) a portion of the sapphire wafer having the thickness greater than 125 microns.

2. The dicing method as set forth in claim 1, wherein the laser scribing produces laser scribe lines passing through a thickness of between 25% and 66% of the wafer thickness.

3. The dicing method as set forth in claim 2, wherein the sapphire wafer has a thickness greater than 125 microns and thinner than 600 microns.

4. The dicing method as set forth in claim 2, wherein each laser scribe line includes two laser scribe line components on opposite sides of the sapphire wafer.

5. The dicing method as set forth in claim 2, wherein each device has a lateral dimension at least twice as large as the thickness of the sapphire wafer.

6. The dicing method as set forth in claim 2, wherein the devices are GaN-based light emitting diode (LED) devices.

7. The dicing method as set forth in claim 1, wherein the laser scribing produces laser scribe lines that pass entirely through the thickness of the sapphire wafer such that the laser scribing effectuates the separating without subsequent fracturing.

8. The dicing method as set forth in claim 1, wherein the method does not include thinning the sapphire substrate.

9. A device die comprising:
an electronic or optoelectronic device; and
a sapphire substrate supporting the electronic or optoelectronic device, the sapphire substrate having a thickness greater than 125 microns and sides generated by laser scribing.

10. The device die as set forth in claim 9, wherein the device is a GaN-based LED device.

11. The device die as set forth in claim 10, wherein the GaN-based LED device has lateral dimensions at least twice as large as the thickness of the sapphire wafer.

12. The device die as set forth in claim 10, wherein the sapphire substrate has a thickness of at least 400 micron.

13. A GaN LED device die comprising:
a GaN-based LED device; and
a sapphire substrate supporting the GaN-based LED device, the sapphire substrate having (i) a thickness greater than 125 microns effective for increased light extraction due to a lower critical angle for total internal reflection and (ii) sides generated by laser scribing.

14. The GaN LED device die as set forth in claim 13, wherein the sapphire substrate has a thickness of at least 400 micron.

15. The GaN LED device die as set forth in claim 13, wherein the sapphire substrate has not been thinned.

16. The GaN LED device die as set forth in claim 13, wherein the GaN-based LED device has a lateral dimension of at least 350 micron.

17. The GaN LED device die as set forth in claim 13, wherein the sapphire substrate is shaped by the laser scribing.
